(19) United States
(12) Patent Application Publication
(10) Pub. No.: US 2026/0165009 A1
(43) Pub. Date: Jun. 11, 2026

(54) DISPLAY PANEL AND DISPLAY DEVICE

(71) Applicant: Shenzhen China Star Optoelectronics Semiconductor Display Technology Co., Ltd., Shenzhen, Guangdong (CN)

(72) Inventors: Zhiyuan YIN, Shenzhen, Guangdong (CN); Linya CHEN, Shenzhen, Guangdong (CN); Jinchuan LI, Shenzhen, Guangdong (CN); Shiyuan LIU, Shenzhen, Guangdong (CN); Ting SHI, Shenzhen, Guangdong (CN); Honggang GU, Shenzhen, Guangdong (CN)

(73) Assignee: Shenzhen China Star Optoelectronics Semiconductor Display Technology Co., Ltd., Shenzhen, Guangdong (CN)

(21) Appl. No.: 18/706,012

(22) PCT Filed: Mar. 7, 2024
(86) PCT No.: PCT/CN2024/080463

§ 371 Date: Apr. 30, 2024

(30) Foreign Application Priority Data
Mar. 1, 2024 (CN) 202410240128.9

(51) Int. Cl. H10K 59/80; H10K 59/126

(52) U.S. Cl. CPC H10K 59/8791; H10K 59/126

(57) ABSTRACT

A display panel and a display device are provided. The display panel includes a light-emitting layer with multiple light-emitting units and a light-modulating layer located on a light-exiting side of the light-emitting units. The light-modulating layer exhibits a transmittance of greater than or equal to 80% for light emitted by the light-emitting units with wavelengths greater than 450 nanometers, and a transmittance of less than or equal to 20% for light with wavelengths less than or equal to 450 nanometers.

### TECHNICAL FIELD

The present application relates to a field of display technology, specifically to a display panel and a display device.

### DESCRIPTION OF RELATED ART

Organic light-emitting diode (OLED) display panels, which have the characteristics of self-emission, high brightness, high efficiency, low voltage drive, wide viewing angle, high contrast, and high response, thus have a wide range of application prospects. OLED display panels use organic luminescent materials for display and usually employ filters to selectively filter specific light rays to enhance the display effect of OLED display panels. However, existing filters, while allowing the light emitted by OLED display panels to pass through, cannot prevent short-wavelength light in the ambient light from shining onto the organic luminescent materials, causing the organic luminescent materials to decompose under the irradiation of short-wavelength light, which reduces the service life of the OLED display panels.

Therefore, there is an urgent need for a display panel and a display device to solve the above technical problem.

### SUMMARY OF INVENTION

The disclosure provides a display panel and a display device that can alleviate the technical problem of current filters' inability to block short-wavelength light from ambient light from shining onto organic luminescent material of the display panel while maintaining transparency to the light emitted by the display panel, which causes a reduction in the service life of the display panel.

In order to solve the above problems, the technical solutions provided by this application are as follows:

The present disclosure provides a display panel, including:
a light-emitting layer, including a plurality of light-emitting units; and
a light-modulating layer, located on a light-exiting side of the light-emitting units;
wherein the light-modulating layer exhibits a transmittance of greater than or equal to 80% for light emitted by the light-emitting units with wavelengths greater than 450 nanometers, and a transmittance of less than or equal to 20% for light with wavelengths less than or equal to 450 nanometers.

The present disclosure further provides a display device, including a display panel, wherein the display panel includes:
a light-emitting layer, including a plurality of light-emitting units; and
a light-modulating layer, located on a light-exiting side of the light-emitting units;
wherein the light-modulating layer exhibits a transmittance of greater than or equal to 80% for light emitted by the light-emitting units with wavelengths greater than 450 nanometers, and a transmittance of less than or equal to 20% for light with wavelengths less than or equal to 450 nanometers.

### BRIEF DESCRIPTION OF DRAWINGS

FIG. 1 is a first structural schematic view of a display panel according to one embodiment of the present disclosure.

FIG. 2 is a second structural schematic view of the display panel according to one embodiment of the present disclosure.

FIG. 3 is a first structural schematic view of a light-modulating layer of the display panel according to one embodiment of this disclosure.

FIG. 4 is a second structural schematic view of the light-modulating layer of the display panel according to one embodiment of this disclosure.

FIG. 5 is a schematic diagram showing optical constants of TiO₂ used in the light-modulating layer according to one embodiment of this disclosure.

FIG. 6 is a schematic diagram showing optical constants of SiO₂ used in the light-modulating layer according to one embodiment of this disclosure.

FIG. 7 is a schematic diagram of a light transmittance of light emitted by a second light-emitting unit under a zero-degree viewing angle when a thickness of a spacer of the light-modulating layer is 120 nm according to one embodiment of this disclosure.

FIG. 8 is a schematic diagram according to one embodiment of this disclosure, showing changes in light transmittance and reflectance of the light emitted by the second light-emitting unit under the zero-degree viewing angle as a thickness of the spacer varies.

FIG. 9 is a schematic diagram of a far-field radiation spectrum of the second light-emitting unit under the zero-degree viewing angle according to one embodiment of this disclosure.

FIG. 10 is a schematic diagram showing optical constants of a traditional organic dye color filter.

FIG. 11 is a schematic diagram of light transmittance and reflectance of the light emitted by the second light-emitting unit under the zero-degree viewing angle when using the traditional organic dye color filter.

FIG. 12 is a schematic diagram of the far-field radiation spectrum of the second light-emitting unit under a zero-degree viewing angle when using a traditional organic dye filter and the light-modulating layer according to one embodiment of this disclosure.

FIG. 13 is a schematic structural view showing a display device according to one embodiment of this disclosure.

### DETAILED DESCRIPTION OF EMBODIMENTS OF THE INVENTION

The present application provides a display panel and a display device. To make the objectives, technical solutions, and effects of this application clearer and more precise, the following explanation is provided in further detail with reference to the accompanying drawings and specific embodiments. It should be understood that the specific embodiments described here are only used to explain this application and are not intended to limit the scope of this application.

Currently, filters are unable to block short-wavelength light from ambient light from shining onto the organic luminescent materials of the display panel while maintaining transparency to the light emitted by the display panel. This leads to a technical problem where the decomposition of organic materials results in a reduced service life of the display panel.

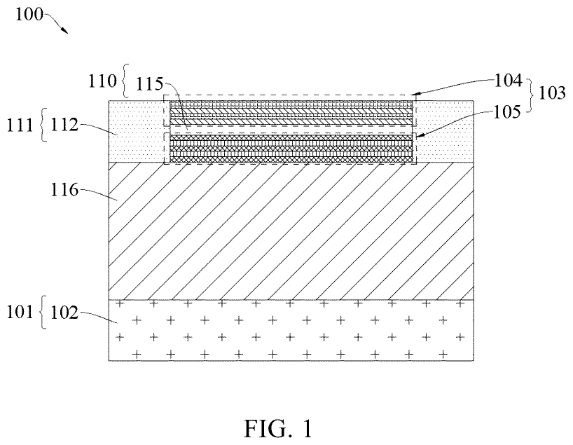

Please refer to FIGS. 1 to 4. One embodiment of the present application provides a display panel 100, including:
a light-emitting layer 101, including a plurality of light-emitting units 102;
a light-modulating layer 103, located on a light-exiting side of the light-emitting units 102;
wherein the light-modulating layer 103 exhibits a transmittance of greater than or equal to 80% for light emitted by the light-emitting units 102 with wavelengths greater than 450 nanometers, and a transmittance of less than or equal to 20% for light with wavelengths less than or equal to 450 nanometers.

By implementing the light-modulating layer 103, which maintains transmission of light emitted by the light-emitting units 102, the exposure of the light-emitting units 102 to external environmental light with wavelengths less than or equal to 450 nanometers is reduced. This reduction in exposure decreases the decomposition of organic luminescent materials within the light-emitting units 102, thereby enhancing the lifespan of the display panel 100.

The technical solution of the present disclosure is described with reference to specific embodiments.

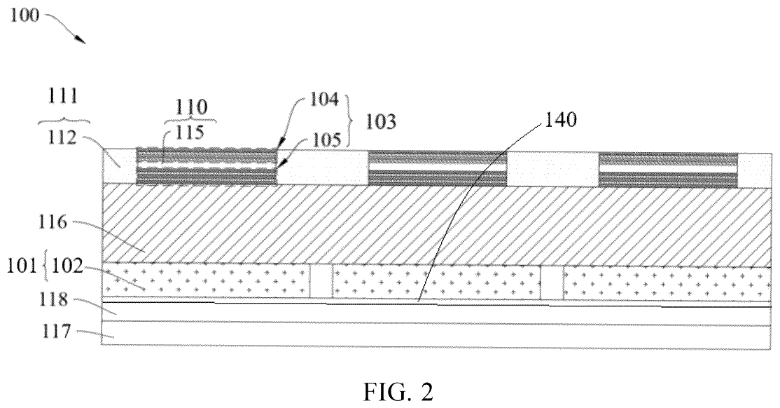

Please refer to FIG. 1 and FIG. 2. In this embodiment, the light-modulating layer 103 is located on the light-exiting side of the light-emitting units 102, that is, the light-modulating layer 103 is situated on a side from which the light-emitting units 102 emit light. The light emitted by the light-emitting units 102 pass through the light-modulating layer 103 before exiting.

Referring to FIG. 2, in some embodiments, the display panel 100 further includes a substrate. The light-emitting layer 101 is located on one side of the substrate. When the light emitted by the light-emitting units 102 exits through the substrate, the light-modulating layer 103 is located between the substrate and the light-emitting layer 101. When the light emitted by the light-emitting units 102 exits in a direction away from the substrate, that is, when the substrate is on a backlight side of the light-emitting layer 101, the light-modulating layer 103 is located on one side of the light-emitting layer 101 that is away from the substrate.

Please refer to FIGS. 1 to 4. The light-modulating layer 103 includes a first light-modulating part 104 and a second light-modulating part 105, where the first light-modulating part 104 is located on one side of the second light-modulating part 105 that is away from the light-emitting layer 101. A transmittance of the first light-modulating part 104 for light with wavelengths less than or equal to 450 nanometers is less than a transmittance of the second light-modulating part 105 for light with wavelengths less than or equal to 450 nanometers. The first light-modulating part 104 being positioned on the side of the second light-modulating part 105 that is away from the light-emitting layer 101 meaning that the first light-modulating part 104 is closer to the external environment. The arrangement where the first light-modulating part 104 has a lower transmittance for light with wavelengths less than or equal to 450 nanometers compared to the second light-modulating part 105 is more advantageous for blocking short-wavelength light from the external environment from entering the display panel 100, thereby helping to extend the lifespan of the display panel 100.

In some embodiments, the transmittance of the light-modulating layer 103 for light with wavelengths less than or equal to 450 nanometers is less than or equal to 20%, for example, the transmittance can be 0%, 1%, 2%, 5%, 8%, 10%, 11%, 12%, 14%, 15%, 16%, 18%, etc. Furthermore, the transmittance of the light-modulating layer 103 for light with wavelengths less than or equal to 450 nanometers being less than or equal to 10% is beneficial for further reducing the entry of short-wavelength light from the external environment into the display panel 100, thereby enhancing the lifespan of the display panel 100.

In some embodiments, the transmittance of the light-modulating layer 103 for light emitted by the light-emitting units 102 is greater than or equal to 80%, for example, the transmittance can be 81%, 82%, 83%, 84%, 85%, 86%, 87%, 88%, 89%, 90%, 92%, 95%, 96%, 98%, 100%, etc., to ensure the light output efficiency of the light emitted by the light-emitting units 102.

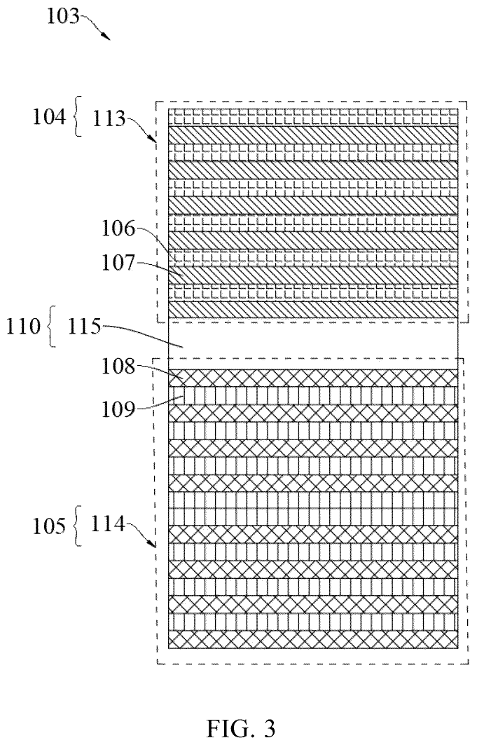

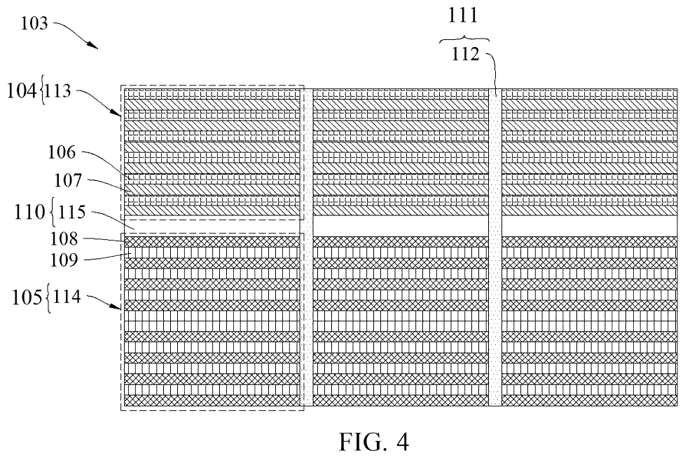

Please refer to FIG. 3 and FIG. 4. In some embodiments, the first light-modulating part 104 comprises at least one first refractive index sub-layer 106 and at least one second refractive index sub-layer 107. Along a direction from the light-emitting layer 101 to the light-modulating layer 103, the first refractive index sub-layer 106 and the second refractive index sub-layer 107 are alternately arranged, with a refractive index of the first refractive index sub-layer 106 being different from a refractive index of the second refractive index sub-layer 107. The first light-modulating part 104, composed of the first refractive index sub-layer 106 and the second refractive index sub-layer 107, forms a Bragg reflector in the direction from the light-emitting layer 101 to the light-modulating layer 103, with the alternately layered first and second refractive index sub-layers 106, 107 of different refractive indexes. This arrangement maintains the transmission of light emitted by the light-emitting units 102 while specifically reducing the transmittance of short-wavelength light. Using the first refractive index sub-layer 106 and the second refractive index sub-layer 107 to form a Bragg reflector avoids the use of organic dyes, thus preventing the issues of poor uniformity in film layer thickness and instability in performance that arise due to the large size and uneven distribution of organic dyes.

In some embodiments, the refractive index of the first refractive index sub-layer 106 is greater than the refractive index of the second refractive index sub-layer 107; alternatively, the refractive index of the first refractive index sub-layer 106 is less than the refractive index of the second refractive index sub-layer 107. Along the direction from the light-emitting layer 101 to the light-modulating layer 103, the one among the first refractive index sub-layer 106 and the second refractive index sub-layer 107 that is closest to the light-emitting layer 101 can be the one with the higher refractive index or the one with the lower refractive index.

Please refer to FIGS. 1 to 4. In some embodiments, among the multiple layers of the first light-modulating part 104, the refractive index of the layer closest to the light-emitting layer 101 is different from the refractive index of the layer furthest from the light-emitting layer 101. For example, in the multiple layers of the first light-modulating part 104, if the layer closest to the light-emitting layer 101 is the one with the lower refractive index out of the first refractive index sub-layer 106 and the second refractive index sub-layer 107, then the layer furthest from the light-emitting layer 101 in the multiple layers of the first light-modulating part 104 is the one with the higher refractive index out of the first refractive index sub-layer 106 and the second refractive index sub-layer 107.

Please refer to FIGS. 1 to 4. In some embodiments, the number of layers of the first refractive index sub-layer 106 within the first light-modulating part 104 is greater than or equal to 1, for instance, the number can be 2, 3, 4, 5, 6, etc. Similarly, the number of layers of the second refractive index sub-layer 107 within the first light-modulating part 104 is greater than or equal to 1, for example, the number can also be 2, 3, 4, 5, 6, etc. The sum of the layers of the first refractive index sub-layer 106 and the second refractive index sub-layer 107 within the first light-modulating part 104 is an even number, such as 2, 4, 6, 8, 10, 12, etc. The number of layers of the first refractive index sub-layer 106 is the same as the number of layers of the second refractive index sub-layer 107. When the number of layers of the first refractive index sub-layer 106 is more than 1, and the number of layers of the second refractive index sub-layer 107 is more than 1, the alternating arrangement of multiple first refractive index sub-layers 106 with multiple second refractive index sub-layers 107 is more beneficial for the first light-modulating part 104 to maintain the transmission of light emitted by the light-emitting units 102 while specifically reducing the transmittance of short-wavelength light.

In some embodiments, when the number of layers of the first refractive index sub-layer 106 is more than 1, the thicknesses of different first refractive index sub-layers 106 may be the same or vary. The thickness of each first refractive index sub-layer 106 can be set based on the wavelength of light for which the transmittance is specifically reduced. Specifically, the thickness of each first refractive index sub-layer 106 is less than the wavelength of light targeted for reduced transmittance. For example, for light with a targeted reduction in transmittance at a wavelength of 450 nanometers, the thickness of each first refractive index sub-layer 106 is less than 450 nanometers. Similarly, when the number of layers of the second refractive index sub-layer 107 is more than 1, the thicknesses of different second refractive index sub-layers 107 may be the same or vary. The thickness of each second refractive index sub-layer 107 can also be set based on the wavelength of light for which the transmittance is specifically reduced. Specifically, the thickness of each second refractive index sub-layer 107 is less than the wavelength of light targeted for reduced transmittance. For instance, for light with a targeted reduction in transmittance at a wavelength of 450 nanometers, the thickness of each second refractive index sub-layer 107 is less than 450 nanometers.

In some embodiments, the thickness of each first refractive index sub-layer 106 can be greater than or equal to half the wavelength of the light targeted for reduced transmittance. For example, for light with a targeted reduction in transmittance at a wavelength of 450 nanometers, the thickness of each first refractive index sub-layer 106 is greater than or equal to 225 nanometers. Alternatively, the thickness of each first refractive index sub-layer 106 can be less than half the wavelength of the light targeted for reduced transmittance. For instance, for light targeted at a wavelength of 450 nanometers, the thickness of each first refractive index sub-layer 106 is less than 225 nanometers. Similarly, the thickness of each second refractive index sub-layer 107 can be greater than or equal to half the wavelength of the light targeted for reduced transmittance. For example, for light with a targeted reduction in transmittance at a wavelength of 450 nanometers, the thickness of each second refractive index sub-layer 107 is greater than or equal to 225 nanometers. Alternatively, the thickness of each second refractive index sub-layer 107 can be less than half the wavelength of the light targeted for reduced transmittance. For instance, using light with a targeted reduction in transmittance at a wavelength of 450 nanometers as an example, the thickness of each second refractive index sub-layer 107 is less than 225 nanometers.

In some embodiments, the thickness of each first refractive index sub-layer 106 can be greater than or equal to one quarter of the wavelength of the light targeted for reduced transmittance. For instance, with light targeted at a wavelength of 450 nanometers, the thickness of each first refractive index sub-layer 106 would be greater than or equal to 112.5 nanometers. Alternatively, the thickness of each first refractive index sub-layer 106 can be less than one quarter of the wavelength of the targeted light, meaning for light at a wavelength of 450 nanometers, each first refractive index sub-layer 106 would have a thickness less than 112.5 nanometers. Similarly, the thickness of each second refractive index sub-layer 107 can be greater than or equal to one quarter of the wavelength of the light targeted for reduced transmittance. For example, for light with a wavelength targeted at 450 nanometers, each second refractive index sub-layer 107 would have a thickness greater than or equal to 112.5 nanometers. Alternatively, the thickness of each second refractive index sub-layer 107 can be less than one quarter of the wavelength of the targeted light. For example, for light at a wavelength of 450 nanometers, each second refractive index sub-layer 107 has a thickness less than 112.5 nanometers.

In some embodiments, the thickness of each first refractive index sub-layer 106 and the thickness of each second refractive index sub-layer 107 can be adjusted according to the following formula within a range that is less than the wavelength of light targeted for reduced transmittance:

$${d}_{1} = {λ}_{1} / 4 {n}_{1}$$

Wherein, d₁ represents a theoretical thickness of the first refractive index sub-layer 106 or the second refractive index sub-layer 107, λ₁ represents the wavelength of light for which the first light-modulating part 104 is specifically designed to reduce transmittance, and n₁ represents the refractive index of either the first refractive index sub-layer 106 or the second refractive index sub-layer 107.

Please refer to FIGS. 1 to 4. In some embodiments, the second light-modulating part 105 comprises at least one third refractive index sub-layer 108 and at least one fourth refractive index sub-layer 109. Along the direction from the light-emitting layer 101 to the light-modulating layer 103, the third refractive index sub-layer 108 and the fourth refractive index sub-layer 109 are arranged alternately, with a refractive index of the third refractive index sub-layer 108 being different from a refractive index of the fourth refractive index sub-layer 109. The second light-modulating part 105, consisting of the third refractive index sub-layer 108 and the fourth refractive index sub-layer 109, forms a Bragg reflector in the direction from the light-emitting layer 101 to the light-modulating layer 103 with the alternately layered third and fourth refractive index sub-layers 108, 109 of different refractive indexes. This configuration reduces the transmittance of short-wavelength light while specifically enhancing the transmittance of light emitted by the light-emitting units 102. By forming a Bragg reflector with the third refractive index sub-layer 108 and the fourth refractive index sub-layer 109, the use of organic dyes is avoided, thus preventing the issues of poor uniformity in film layer thickness and instability in performance that are caused by the large size and uneven distribution of organic dyes.

In some embodiments, the refractive index of the third refractive index sub-layer 108 is either greater than or less than the refractive index of the fourth refractive index sub-layer 109. Along the direction from the light-emitting layer 101 to the light-modulating layer 103, the one among the third refractive index sub-layer 108 and the fourth refractive index sub-layer 109 that is closest to the light-emitting layer 101 can be either the one with the higher refractive index or the one with the lower refractive index between the third and fourth refractive index sub-layers 108, 109.

Please refer to FIGS. 1 to 4. In some embodiments, within the multiple layers of the second light-modulating part 105, the refractive index of the layer closest to the light-emitting layer 101 is the same as the refractive index of the layer furthest from the light-emitting layer 101. For instance, in the multiple layers of the second light-modulating part 105, if the layer closest to the light-emitting layer 101 is the one with the higher refractive index between the third refractive index sub-layer 108 and the fourth refractive index sub-layer 109, then the layer furthest from the light-emitting layer 101 in the multiple layers of the second light-modulating part 105 is also the one with the higher refractive index between the third and fourth refractive index sub-layers 108, 109.

In some embodiments, the number of layers of the third refractive index sub-layer 108 within the second light-modulating part 105 is greater than or equal to 1, for example, the number can be 2, 3, 4, 5, 6, etc. Similarly, the number of layers of the fourth refractive index sub-layer 109 within the second light-modulating part 105 is greater than or equal to 1, for instance, the number can be 2, 3, 4, 5, 6, etc. The total number of layers of the third refractive index sub-layer 108 and the fourth refractive index sub-layer 109 within the second light-modulating part 105 can be an even number, such as 2, 4, 6, 8, 10, 12, etc. The number of layers of the third refractive index sub-layer 108 can be the same as the number of layers of the fourth refractive index sub-layer 109. When the number of layers of the third refractive index sub-layer 108 is more than 1, and the number of layers of the fourth refractive index sub-layer 109 is more than 1, the alternating arrangement of multiple third refractive index sub-layers 108 with multiple fourth refractive index sub-layers 109 enhances the ability of the second light-modulating part 105 to reduce the transmittance of short-wavelength light while specifically increasing the transmittance of light emitted by the light-emitting units 102.

In some embodiments, when the number of layers of the third refractive index sub-layer 108 is more than 1, the thickness of each third refractive index sub-layer 108 can be the same or differ from each other. The thickness of each third refractive index sub-layer 108 can be set based on the wavelength of light for which the transmittance is specifically intended to be increased. Specifically, the thickness of each third refractive index sub-layer 108 is less than the wavelength of light targeted for enhanced transmittance. For example, for light targeted to have its transmittance increased at a wavelength of 522 nanometers, the thickness of each third refractive index sub-layer 108 is less than 522 nanometers. Similarly, when the number of layers of the fourth refractive index sub-layer 109 is more than 1, the thickness of each fourth refractive index sub-layer 109 can be the same or vary. The thickness of each fourth refractive index sub-layer 109 can be set according to the wavelength of light for which the transmittance is specifically intended to be increased. Specifically, the thickness of each fourth refractive index sub-layer 109 is less than the wavelength of light targeted for enhanced transmittance. For instance, for light with a wavelength of 522 nanometers targeted for increased transmittance, the thickness of each fourth refractive index sub-layer 109 is less than 522 nanometers.

In some embodiments, the thickness of each third refractive index sub-layer 108 can be greater than or equal to half the wavelength of the light targeted for increased transmittance. For example, for light with a wavelength of 522 nanometers targeted for reduced transmittance, the thickness of each third refractive index sub-layer 108 is greater than or equal to 261 nanometers. Alternatively, the thickness of each third refractive index sub-layer 108 can be less than half the wavelength of the light targeted for reduced transmittance. For instance, for light with a wavelength of 522 nanometers targeted for reduced transmittance, each third refractive index sub-layer 108 has a thickness less than 261 nanometers. Similarly, the thickness of each fourth refractive index sub-layer 109 can be greater than or equal to half the wavelength of the light targeted for increased transmittance. For example, for light with a wavelength of 522 nanometers targeted for increased transmittance, each fourth refractive index sub-layer 109 has a thickness greater than or equal to 261 nanometers. Alternatively, the thickness of each fourth refractive index sub-layer 109 can be less than half the wavelength of the light targeted for increased transmittance. For instance, for light with a wavelength of 522 nanometers targeted for increased transmittance, each fourth refractive index sub-layer 109 has a thickness less than 261 nanometers.

In some embodiments, the thickness of each third refractive index sub-layer 108 can be greater than or equal to one quarter of the wavelength of the light targeted for increased transmittance. For instance, with light targeted for increased transmittance at a wavelength of 522 nanometers, each third refractive index sub-layer 108 can have a thickness greater than or equal to 130.5 nanometers. Alternatively, the thickness of each third refractive index sub-layer 108 can be less than one quarter of the wavelength of the light targeted for increased transmittance. For example, for light targeted at a wavelength of 522 nanometers for increased transmittance, each third refractive index sub-layer 108 has a thickness less than 130.5 nanometers. Similarly, the thickness of each fourth refractive index sub-layer 109 can be greater than or equal to one quarter of the wavelength of the light targeted for increased transmittance. For example, for light targeted at a wavelength of 522 nanometers for increased transmittance, each fourth refractive index sub-layer 109 has a thickness greater than or equal to 130.5 nanometers. Alternatively, the thickness of each fourth refractive index sub-layer 109 can be less than one quarter of the wavelength of the light targeted for increased transmittance. For instance, with light targeted for increased transmittance at a wavelength of 522 nanometers, each fourth refractive index sub-layer 109 would have a thickness less than 130.5 nanometers.

In some embodiments, the thickness of each third refractive index sub-layer 108 and each fourth refractive index sub-layer 109 can be adjusted according to the following formula, within a range that is less than the wavelength of light targeted for increased transmittance:

$${d}_{2} = {λ}_{2} / 4 {n}_{2}$$

Wherein, d₂ represents a theoretical thickness of either the third refractive index sub-layer 108 or the fourth refractive index sub-layer 109, k₂ represents the wavelength of light for which the second light-modulating part 105 is specifically designed to increase transmittance, and n₂ represents the refractive index of either the third refractive index sub-layer 108 or the fourth refractive index sub-layer 109. This formula allows for the precise adjustment of the layer thicknesses to optimize the modulation of light transmittance through the display panel, enhancing the display's visual performance by targeting specific light wavelengths.

In some embodiments, the materials of the first refractive index sub-layer 106, the second refractive index sub-layer 107, the third refractive index sub-layer 108, and the fourth refractive index sub-layer 109 have a refractive index greater than or equal to 90% within the visible light wavelength range. The refractive index can include values such as 92%, 93%, 94%, 95%, 96%, 97%, 98%, 99%, 100%, etc. Furthermore, the materials of the first refractive index sub-layer 106, the second refractive index sub-layer 107, the third refractive index sub-layer 108, and the fourth refractive index sub-layer 109 have a refractive index greater than or equal to 92% within the visible light wavelength range. The visible light wavelength range refers to light with wavelengths in the range of 380 nanometers to 780 nanometers.

In some embodiments, the material with the higher refractive index among the first refractive index sub-layer 106 and the second refractive index sub-layer 107, compared to the material with the lower refractive index among the first refractive index sub-layer 106 and the second refractive index sub-layer 107, has a better capability to block water and oxygen. Therefore, within the first light-modulating part 104, a total thickness of the material with the higher refractive index among the first refractive index sub-layer 106 and the second refractive index sub-layer 107 is greater than a total thickness of the material with the lower refractive index among the first refractive index sub-layer 106 and the second refractive index sub-layer 107. This means that if the refractive index of the first refractive index sub-layer 106 is greater than the refractive index of the second refractive index sub-layer 107, then a thickness proportion of the first refractive index sub-layer 106 within the first light-modulating part 104 is greater than a thickness proportion of the second refractive index sub-layer 107 within the first light-modulating part 104. Alternatively, if the refractive index of the first refractive index sub-layer 106 is less than the refractive index of the second refractive index sub-layer 107, then the thickness proportion of the first refractive index sub-layer 106 within the first light-modulating part 104 is less than the thickness proportion of the second refractive index sub-layer 107 within the first light-modulating part 104. This arrangement optimizes the protective and optical properties of the light-modulating part by leveraging the material characteristics of the sub-layers.

Similarly, the material with the higher refractive index among the third refractive index sub-layer 108 and the fourth refractive index sub-layer 109, compared to the material with the lower refractive index among the third refractive index sub-layer 108 and the fourth refractive index sub-layer 109, possesses a superior ability to block water and oxygen. Therefore, within the second light-modulating part 105, a total thickness of the material with the higher refractive index among the third refractive index sub-layer 108 and the fourth refractive index sub-layer 109 is greater than a total thickness of the material with the lower refractive index among the third refractive index sub-layer 108 and the fourth refractive index sub-layer 109. This means that if the refractive index of the third refractive index sub-layer 108 is greater than the refractive index of the fourth refractive index sub-layer 109, then a thickness proportion of the third refractive index sub-layer 108 within the second light-modulating part 105 is greater than a thickness proportion of the fourth refractive index sub-layer 109 within the second light-modulating part 105. Alternatively, if the refractive index of the third refractive index sub-layer 108 is less than the refractive index of the fourth refractive index sub-layer 109, then a thickness proportion of the third refractive index sub-layer 108 within the second light-modulating part 105 is less than a thickness proportion of the fourth refractive index sub-layer 109 within the second light-modulating part 105. This strategy enhances the protective and optical efficiency of the light-modulating part by utilizing the material characteristics of the sub-layers effectively.

In some embodiments, the material of the higher refractive index among the first refractive index sub-layer 106 and the second refractive index sub-layer 107 can be selected from at least one of the oxides of titanium (Ti) or zirconium (Zr), such as TiO₂, ZrO₂, etc. Similarly, the material of the higher refractive index among the third refractive index sub-layer 108 and the fourth refractive index sub-layer 109 can be selected from at least one of the oxides of titanium (Ti) or zirconium (Zr), such as at least one of TiO₂, ZrO₂, etc.

In some embodiments, the material of the lower refractive index among the first refractive index sub-layer 106 and the second refractive index sub-layer 107 can be selected from at least one of silicon oxide, silicon nitride, and silicon oxynitride, such as at least one of silica (SiO₂), silicon nitride (Si₃N₄), or silicon oxynitride. Similarly, the material of the lower refractive index among the third refractive index sub-layer 108 and the fourth refractive index sub-layer 109 can be selected from at least one of silicon oxide, silicon nitride, and silicon oxynitride, such as at least one of silica, silicon nitride, or silicon oxynitride.

In some embodiments, a thickness of the first light-modulating part 104 is greater than or equal to 380 nanometers and less than or equal to 1.5 micrometers, for instance, the thickness can be 0.5 micrometers, 0.6 micrometers, 0.8 micrometers, 1 micrometer, 1.2 micrometers, 1.3 micrometers, 1.4 micrometers, etc. Similarly, a thickness of the second light-modulating part 105 is greater than or equal to 380 nanometers and less than or equal to 1.5 micrometers, for example, the thickness can be 0.5 micrometers, 0.6 micrometers, 0.8 micrometers, 1 micrometer, 1.2 micrometers, 1.3 micrometers, 1.4 micrometers, etc. This specification allows for a range of thicknesses that can be optimized for the performance of the light-modulating parts in the display panel, considering both optical properties and physical durability.

In some embodiments, an absolute value of a difference between the refractive index of the first refractive index sub-layer 106 and the refractive index of the second refractive index sub-layer 107 is greater than or equal to 0.3. For example, the absolute value of the difference can be 0.31, 0.32, 0.33, 0.34, 0.35, 0.36, 0.37, 0.38, 0.39, 0.4, 0.5, 0.6, 0.7, 0.8, etc. This is advantageous for more effectively targeting the reduction of the transmittance of short-wavelength light.

In some embodiments, an absolute value of a difference between the refractive index of the third refractive index sub-layer 108 and the refractive index of the fourth refractive index sub-layer 109 is greater than or equal to 0.3. For example, the absolute value of the difference can be 0.31, 0.32, 0.33, 0.34, 0.35, 0.36, 0.37, 0.38, 0.39, 0.4, 0.5, 0.6, 0.7, 0.8, etc. This is advantageous for more effectively targeting the enhancement of the transmittance of light emitted by the light-emitting units 102.

In some embodiments, the light-modulating layer 103 also includes a spacer 110 located between the first light-modulating part 104 and the second light-modulating part 105. The incorporation of the spacer 110, which separates the first light-modulating part 104 from the second light-modulating part 105, is advantageous for preventing mutual interference between the first light-modulating part 104 and the second light-modulating part 105. This separation effectively enhances the ability of the first light-modulating part 104 to reduce the transmittance of short-wavelength light and the ability of the second light-modulating part 105 to increase the transmittance of light emitted by the light-emitting units 102.

In some embodiments, along the direction from the light-emitting layer 101 to the light-modulating layer 103, the light-modulating layer 103 is composed of the second light-modulating part 105, the spacer 110, and the first light-modulating part 104 stacked in sequence.

Please refer to FIGS. 1 to 4. In some embodiments, a thickness of the spacer 110 is greater than the thickness of any of the first refractive index sub-layer 106, the second refractive index sub-layer 107, the third refractive index sub-layer 108, or the fourth refractive index sub-layer 109. Preferably, a ratio of the thickness of the spacer 110 to the thickness of the first light-modulating part 104 is greater than or equal to 1 and less than or equal to 10, for example, the ratio can be 2, 4, 5, 6, 8, etc.; and/or, a ratio of the thickness of the spacer 110 to the thickness of the second light-modulating part 105 is greater than or equal to 1 and less than or equal to 10, for instance, the ratio can be 2, 4, 5, 6, 8, etc. The thickness of the spacer 110 being in a ratio greater than or equal to 1 and less than or equal to 10 with respect to the thickness of the first light-modulating part 104 and/or the thickness of the spacer 110 being in a ratio greater than or equal to 1 and less than or equal to 10 with respect to the second light-modulating part 105 is beneficial for adequately separating the first light-modulating part 104 and the second light-modulating part 105 by an appropriate thickness range. The refractive index of the higher one among the first refractive index sub-layer and the second refractive index sub-layer is greater than the refractive index of the spacer of the light-modulating layer. And/or, the refractive index of the higher one among the third refractive index sub-layer and the fourth refractive index sub-layer is greater than the refractive index of the spacer of the light-modulating layer.

Please refer to FIGS. 1 to 4. In some embodiments, the display panel 100 further includes a light-shielding layer 111. The light-shielding layer 111 includes a plurality of light-shielding sub-parts 112. An orthographic projection of the light-shielding sub-parts 112 on the light-emitting layer 101 is arranged around the light-emitting units 102.

Referring to FIG. 2 and FIG. 4, in some embodiments, the first light-modulating part 104 includes a plurality of first sub-parts 113, each first sub-part 113 is correspondingly aligned with one light-emitting unit 102, and the light-shielding sub-parts 112 are arranged to surround the first sub-parts 113. The light-shielding sub-parts 112 are co-layered with at least one layer of the first refractive index sub-layer 106 and/or, the light-shielding sub-parts 112 are co-layered with at least one layer of the second refractive index sub-layer 107. And/or, the second light-modulating part 105 includes a plurality of second sub-parts 114, each second sub-part 114 is correspondingly aligned with one light-emitting unit 102, and the light-shielding sub-parts 112 are arranged to surround the second sub-parts 114. The light-shielding sub-parts 112 are co-layered with at least one layer of the third refractive index sub-layer 108 and/or, the light-shielding sub-parts 112 are co-layered with at least one layer of the fourth refractive index sub-layer 109.

When the light-shielding sub-parts 112 are arranged to surround the first sub-parts 113 and the second sub-parts 114, the spacer 110 includes a plurality of spacer sub-parts 115. Each of the spacer sub-parts 115 is correspondingly aligned with one light-emitting unit 102, and the light-shielding sub-parts 112 are arranged to surround the spacer sub-parts 115. The light-shielding layer 111 is co-layered with the light-modulating layer 103.

In some embodiments, a material for the light-shielding layer 111 can be selected from black matrix (BM) materials.

Refer to FIGS. 1 and 2, in some embodiments, the display panel 100 further includes a filling layer 116 located between the light-emitting layer 101 and the light-modulating layer 103. The filling layer 116 serves both supportive and encapsulating functions.

In some embodiments, the display panel 100 further includes an anode located between the light-emitting layer 101 and the substrate, with the anode being correspondingly aligned with the light-emitting units 102. A material for the anode can be selected from at least one of indium tin oxide (ITO) and silver, for example, the anode can consist of a triple-layer stack of indium tin oxide-silver-indium tin oxide.

Referring to FIG. 2, in some embodiments, the display panel 100 further includes a thin-film transistor (TFT) layer 118 located between the substrate and the anode. The TFT layer 118 includes a plurality of thin-film transistors that are connected to the anode to control the light-emitting units 102.

In some embodiments, the light-emitting layer 101 includes a hole injection layer, a hole transport layer situated on one side of the hole injection layer that is away from the substrate, a light-emitting material layer located on one side of the hole transport layer that is away from the substrate, an electron transport layer situated on one side of the light-emitting material layer that is away from the substrate, and the electron transport layer. Within the light-emitting units 102 that emit different colors of light, the light-emitting materials in the light-emitting material layer vary.

In some embodiments, the display panel 100 further includes a cathode located on one side of the light-emitting layer 101 that is away from the substrate, and a capping layer (CPL) situated on one side of the cathode that is away from the substrate. The capping layer is used to reduce the total internal reflection of light emitted by the light-emitting units 102 at the cathode.

In some embodiments, the light-emitting units 102 include a first light-emitting sub-unit, a second light-emitting sub-unit, and a third light-emitting sub-unit that respectively emit light of different colors. The first light-emitting sub-unit emits red light, the second light-emitting sub-unit emits green light, and the third light-emitting sub-unit emits blue light. Depending on the different types of display panels and their specific requirements for the transmittance of light emitted by light-emitting units of different colors, the light-modulating layer 103 within different types of display panels 100 can be adjusted, in regard to light of different colors emitted by the respective light-emitting units 102, to specifically enhance the transmittance of light of a certain color. For example, the second light-modulating part 105 can be adjusted to specifically increase the transmittance of light emitted by the light-emitting units 102 that emit red light, or to specifically increase the transmittance of light emitted by the light-emitting units 102 that emit green light, or to specifically increase the transmittance of light (with wavelengths greater than 450 nanometers) emitted by the light-emitting units 102 that emit blue light.

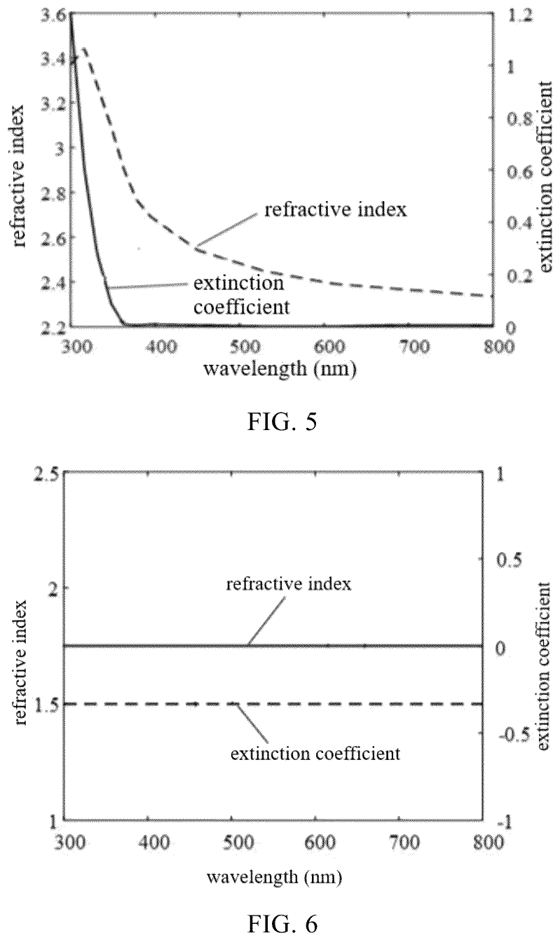

Please refer to FIGS. 5 to 12, the following description outlines a manufacturing method of the light-modulating layer 103, specifically aimed at enhancing the transmittance of light emitted by the light-emitting units (the second light-emitting sub-units) that emit green light.

In this embodiment, the anode consists of a triple-layer stack of indium tin oxide (15 nanometers)-silver (100 nanometers)-indium tin oxide (10 nanometers), the cathode is made of a magnesium silver alloy (15 nanometers), and the capping layer is 60 nanometers thick. The light-emitting layer 101 is composed of a hole injection layer (146.5 nanometers), a hole transport layer (15 nanometers), a light-emitting material layer (30 nanometers), and an electron transport layer (30 nanometers).

Step S100, as shown in FIGS. 5 and 6, involves obtaining optical constants of the high refractive index material TiO₂ and the low refractive index material SiO₂, wherein FIG. 5 shows the refractive index and extinction coefficient of TiO₂, and FIG. 6 shows the refractive index and extinction coefficient of SiO₂.

As shown in FIGS. 3 and 4, taking the case where the refractive index of the first refractive index sub-layer 106 is higher than the refractive index of the second refractive index sub-layer 107 as an example, TiO₂ is used as the material for the first refractive index sub-layer 106, and SiO₂ is used as the material for the second refractive index sub-layer 107, with these materials being stacked in sequence to form the first light-modulating part 104. Similarly, taking the case where the refractive index of the third refractive index sub-layer 108 is higher the refractive index of the fourth refractive index sub-layer 109, TiO₂ is used as the material for the third refractive index sub-layer 108, and SiO₂ is used as the material for the fourth refractive index sub-layer 109, with these materials being stacked in sequence to form the second light-modulating part 105.

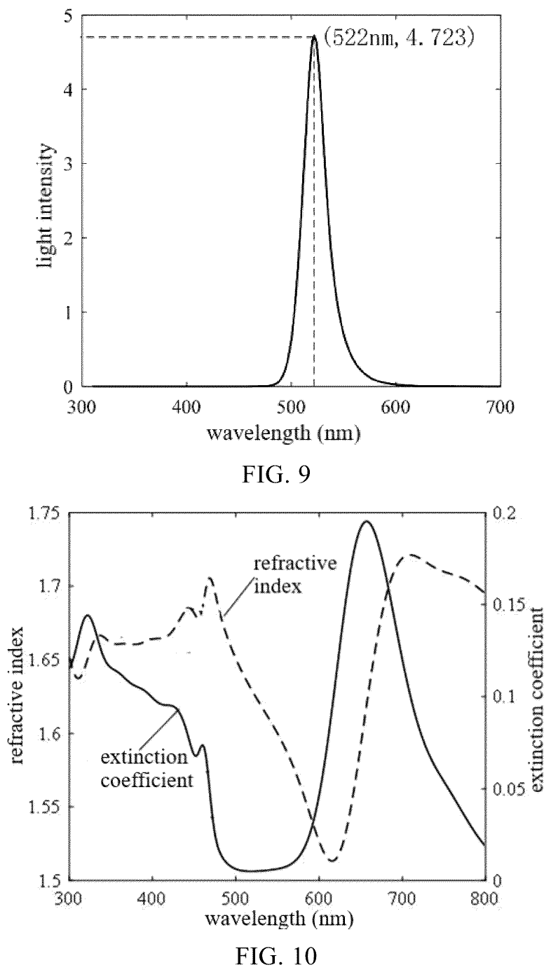

Step S200, as shown in FIG. 9, involves obtaining a central wavelength of the second light-emitting sub-unit based on the far-field radiation spectrum of the light emitted by the second light-emitting sub-unit on one side of the filling layer 116 that is away from the light-emitting layer 101.

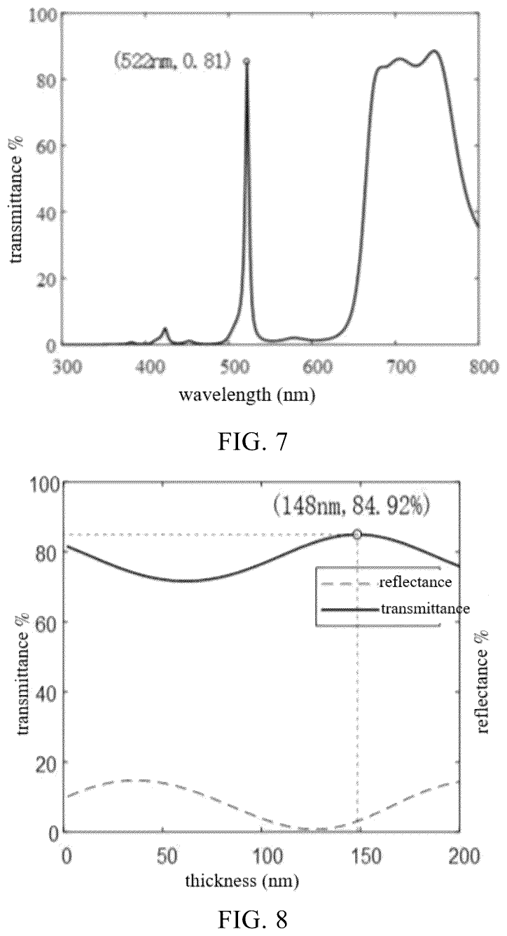

Step S300, as shown in FIG. 7, involves adjusting the thicknesses of the first refractive index sub-layer 106 and the second refractive index sub-layer 107 within the first light-modulating part 104, and the thicknesses of the third refractive index sub-layer 108 and the fourth refractive index sub-layer 109 within the second light-modulating part 105, based on the central wavelength of the second light-emitting sub-unit. The adjustment is made so that the light-modulating layer 103 has a transmittance of less than or equal to 20% for wavelengths less than or equal to 450 nanometers, and a transmittance of greater than or equal to 80% for the central wavelength of the light from the second light-emitting sub-unit. At this point, the thickness of the spacer 110 is fixed at 120 nanometers, and the transmittance of the light-modulating layer 103 for the central wavelength of the light from the second light-emitting sub-unit at a zero-degree viewing angle is obtained. Taking as an example where the refractive index of the first refractive index sub-layer 106 is higher than the refractive index of the second refractive index sub-layer 107, and the refractive index of the third refractive index sub-layer 108 is higher than the refractive index of the fourth refractive index sub-layer 109, the thickness of each first refractive index sub-layer 106 is 27 nm, the thickness of each second refractive index sub-layer 107 is 73 nanometers, the thickness of each third refractive index sub-layer 108 is 52.5 nanometers, and the thickness of each fourth refractive index sub-layer 109 is 87.5 nanometers. The zero-degree viewing angle refers to the viewpoint perpendicular to the plane of the display panel 100.

Step S400, as illustrated in FIG. 8, involves adjusting the thickness of the spacer 110 based on the central wavelength of the second light-emitting sub-unit. The thickness of the spacer 110 that yields the maximum transmittance for the central wavelength of light from the second light-emitting sub-unit at the zero-degree viewing angle is selected as the final thickness for the spacer 110.

Step S500, as shown in FIGS. 9 and 12, involves obtaining the far-field radiation spectrum on one side of the light-modulating layer 103 that is away from the light-emitting layer 101 and obtaining a color saturation of P1=0.9649.

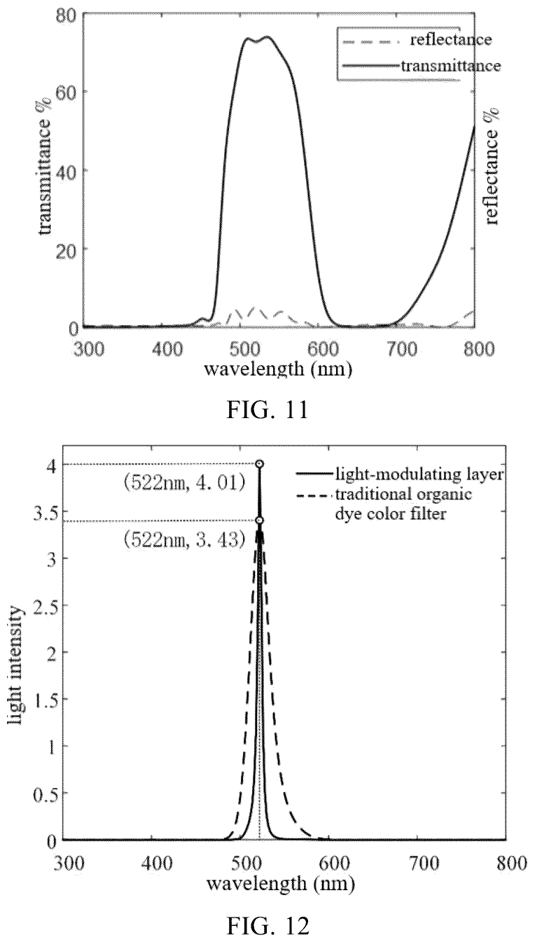

As a comparison, as shown in FIG. 10, the optical constants of a traditional organic dye color filter corresponding to the second light-emitting sub-unit are obtained. As shown in FIG. 11, the reflectance and transmittance of this traditional organic dye color filter for the central wavelength of light from the second light-emitting sub-unit at the zero-degree viewing angle are obtained. As shown in FIG. 12, the far-field radiation spectrum on one side of the traditional organic dye color filter that is away from the light-emitting layer 101 is obtained, and a color saturation of P2=0.8774 is achieved.

From the comparison between FIG. 8 and FIG. 11, it is evident that the light-modulating layer 103 provided in this application has a transmittance for the light emitted by the second light-emitting sub-unit that is greater than or equal to 80%, whereas the transmittance for the light emitted by the second light-emitting sub-unit through the traditional organic dye color filter is less than 80%. This demonstrates the superior transmittance performance of the light-modulating layer 103 for the light emitted by the light-emitting units 102. As shown in FIG. 8, the light-modulating layer 103 provided in this application has a transmittance for light with wavelengths less than or equal to 450 nanometers that is less than or equal to 20% or even close to 0, indicating exceptional light-blocking performance. Furthermore, as shown in FIGS. 9 and 12, the far-field radiation spectrum of the light emitted by the second light-emitting sub-unit after passing through the light-modulating layer 103 provided in this application exhibits a significantly narrower half-bandwidth than the half-bandwidth of the light after passing through the traditional organic dye color filter, with higher color saturation and, under identical light intensity from the second light-emitting unit 102, an enhanced intensity at the central wavelength. This indicates that the light-modulating layer 103 provided in this application not only allows higher transmittance and reduces the irradiation of short-wavelength environmental light on the light-emitting units 102 but also improves the color purity and overall display quality of the display panel 100.

The display panel 100 provided by this disclosure incorporates a light-modulating layer 103. The light-modulating layer 103, while allowing the passage of light emitted by the light-emitting units 102, reduces the incidence of environmental light with wavelengths less than or equal to 450 nanometers on the light-emitting units 102. This reduction in exposure decreases the decomposition of organic luminescent materials within the light-emitting units 102, thereby enhancing the lifespan of the display panel 100.

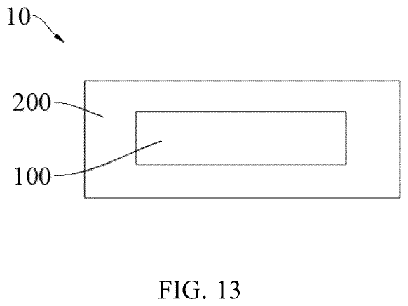

Referring to FIG. 13, the present disclosure further provides a display device 10, which includes the display panel 100 as previously described.

In some embodiments, the display device 10 further includes a device body 200. The device body 200 is integrated with the display panel 100 as a single unit.

For the specific structure of the display panel 100, please refer to any of the embodiments and accompanying drawings of the display panel mentioned above, which will not be reiterated here.

In this embodiment, the device body 200 can include components such as a middle frame and frame adhesive. The display device 10 can be used in various display terminals such as smartphones, tablets, televisions, etc., without being limited to these examples.

The present disclosure discloses a display panel. The display panel includes a light-emitting layer with a plurality of light-emitting units and a light-modulating layer located on a light-exiting side of the light-emitting units. The light-modulating layer has a transmittance of greater than or equal to 80% for light emitted by the light-emitting units with wavelengths greater than 450 nanometers, and a transmittance of less than or equal to 20% for light with wavelengths less than or equal to 450 nanometers. By implementing the light-modulating layer, which maintains the transmission of light emitted by the light-emitting units, the exposure of the light-emitting units to external environmental light with wavelength less than or equal to 450 nanometers is reduced. This reduction in exposure decreases the decomposition of organic luminescent materials in the light-emitting units, thereby enhancing the lifespan of the display panel.

It should be understood that for those skilled in the art, equivalent substitutions or modifications can be made based on the technical solutions and inventive concepts of this application, and all such changes or replacements should fall within the scope of the appended claims to this application.

What is claimed is:

1. A display panel, comprising:
a light-emitting layer, comprising a plurality of light-emitting units; and
a light-modulating layer, located on a light-exiting side of the light-emitting units;
wherein the light-modulating layer exhibits a transmittance of greater than or equal to 80% for light emitted by the light-emitting units with wavelengths greater than 450 nanometers, and a transmittance of less than or equal to 20% for light with wavelengths less than or equal to 450 nanometers.

2. The display panel according to claim 1, wherein the light-modulating layer comprises a first light-modulating part and a second light-modulating part, with the first light-modulating part located on one side of the second light-modulating part that is away from the light-emitting layer;
wherein a transmittance of the first light-modulating part for light with wavelengths less than or equal to 450 nanometers is less than a transmittance of the second light-modulating part for light with wavelengths less than or equal to 450 nanometers.

3. The display panel according to claim 2, wherein the light-modulating layer further comprises a spacer located between the first light-modulating part and the second light-modulating part, a ratio of a thickness of the spacer to a thickness of the first light-modulating part is greater than or equal to 1, and the ratio of the thickness of the spacer to the thickness of the first light-modulating part is less than or equal to 10.

4. The display panel according to claim 2, wherein the light-modulating layer further comprises a spacer located between the first light-modulating part and the second light-modulating part, a ratio of a thickness of the spacer to a thickness of the second light-modulating part is greater than or equal to 1, and the ratio of the thickness of the spacer to the thickness of the second light-modulating part is less than or equal to 10.

5. The display panel according to claim 2, wherein the first light-modulating part comprises at least one first refractive index sub-layer and at least one second refractive index sub-layer; along a direction from the light-emitting layer to the light-modulating layer, the first refractive index sub-layer and the second refractive index sub-layer are arranged alternately, with a refractive index of the first refractive index sub-layer being different from a refractive index of the second refractive index sub-layer.

6. The display panel according to claim 5, wherein the refractive index of the first refractive index sub-layer is greater than the refractive index of the second refractive index sub-layer; relative to a total thickness of the first light-modulating part, a thickness proportion of the first refractive index sub-layer is greater than a thickness proportion of the second refractive index sub-layer.

7. The display panel according to claim 5, wherein the refractive index of the first refractive index sub-layer is less than the refractive index of the second refractive index sub-layer; relative to a total thickness of the first light-modulating part, a thickness proportion of the first refractive index sub-layer is less than a thickness proportion of the second refractive index sub-layer.

8. The display panel according to claim 5, wherein among the first refractive index sub-layer and the second refractive index sub-layer, the one with the higher refractive index employs a material selected from at least one of titanium oxide and zirconium oxide;
among the first refractive index sub-layer and the second refractive index sub-layer, the one with the lower refractive index employs a material selected from at least one of silicon oxide, silicon nitride, and silicon oxynitride.

9. The display panel according to claim 5, wherein the second light-modulating part comprises at least one third refractive index sub-layer and at least one fourth refractive index sub-layer; along the direction from the light-emitting layer to the light-modulating layer, the third refractive index sub-layer and the fourth refractive index sub-layer are arranged alternately, with a refractive index of the third refractive index sub-layer being different from a refractive index of the fourth refractive index sub-layer.

10. The display panel according to claim 9, wherein the refractive index of the third refractive index sub-layer is greater than the refractive index of the fourth refractive index sub-layer; relative to a total thickness of the second light-modulating part, a thickness proportion of the third refractive index sub-layer is greater than a thickness proportion of the fourth refractive index sub-layer.

11. The display panel according to claim 9, wherein the refractive index of the third refractive index sub-layer is less than the refractive index of the fourth refractive index sub-layer; relative to a total thickness of the second light-modulating part, a thickness proportion of the third refractive index sub-layer is less than a thickness proportion of the fourth refractive index sub-layer.

12. The display panel according to claim 9, wherein an absolute value of a difference between the refractive index of the first refractive index sub-layer and the refractive index of the second refractive index sub-layer is greater than or equal to 0.3; and
an absolute value of a difference between the refractive index of the third refractive index sub-layer and the refractive index of the fourth refractive index sub-layer is greater than or equal to 0.3.

13. The display panel according to claim 9, wherein the higher refractive index among the first refractive index sub-layer and the second refractive index sub-layer is greater than a refractive index of the spacer of the light-modulating layer.

14. The display panel according to claim 9, wherein the higher refractive index among the third refractive index sub-layer and the fourth refractive index sub-layer is greater than a refractive index of the spacer of the light-modulating layer.

15. The display panel according to claim 9, wherein among the third refractive index sub-layer and the fourth refractive index sub-layer, the one with the higher refractive index employs a material selected from at least one of titanium oxide and zirconium oxide;
among the third refractive index sub-layer and the fourth refractive index sub-layer, the one with the lower refractive index employs a material selected from at least one of silicon oxide, silicon nitride, and silicon oxynitride.

16. The display panel according to claim 2, wherein the display panel further comprises a light-shielding layer, the light-shielding layer comprises a plurality of light-shielding sub-parts, the first light-modulating part comprises a plurality of first sub-parts, each of the first sub-parts is correspondingly aligned with one of the light-emitting units, and the light-shielding sub-parts are arranged to surround the first sub-parts.

17. The display panel according to claim 2, wherein the display panel further comprises a light-shielding layer, the light-shielding layer comprises a plurality of light-shielding sub-parts, the second light-modulating part comprises a plurality of second sub-parts, each of the second sub-parts is correspondingly aligned with one of the light-emitting units, and the light-shielding sub-parts are arranged to surround the second sub-parts.

18. A display device, comprising a display panel, wherein the display panel comprises:
a light-emitting layer, comprising a plurality of light-emitting units; and
a light-modulating layer, located on a light-exiting side of the light-emitting units;
wherein the light-modulating layer exhibits a transmittance of greater than or equal to 80% for light emitted by the light-emitting units with wavelengths greater than 450 nanometers, and a transmittance of less than or equal to 20% for light with wavelengths less than or equal to 450 nanometers.

19. The display device according to claim 18, wherein the light-modulating layer comprises a first light-modulating part and a second light-modulating part, with the first light-modulating part located on one side of the second light-modulating part that is away from the light-emitting layer;
wherein a transmittance of the first light-modulating part for light with wavelengths less than or equal to 450 nanometers is less than a transmittance of the second light-modulating part for light with wavelengths less than or equal to 450 nanometers.

20. The display device according to claim 19, wherein the light-modulating layer further comprises a spacer located between the first light-modulating part and the second light-modulating part, a ratio of a thickness of the spacer to a thickness of the first light-modulating part is greater than or equal to 1, and the ratio of the thickness of the spacer to the thickness of the first light-modulating part is less than or equal to 10.
